(19) United States
(12) Patent Application Publication
(10) Pub. No.: US 2010/0148805 A1
(43) Pub. Date: Jun. 17, 2010

(54) Fail-Safe System and Test Module, Notably For Use In A Railroad Signaling System

(75) Inventor: Richard Imhoff, Paris (FR)

Correspondence Address: BAKER & HOSTETLER LLP, WASHINGTON SQUARE, SUITE 1100, 1050 CONNECTICUT AVE. N.W., WASHINGTON, DC, 20036-5304, US

(73) Assignee: Thales, Neuilly/Sur/Seine (FR)

(21) Appl. No.: 12/619,942

(22) Filed: Nov. 17, 2009

(30) Foreign Application Priority Data
Nov. 18, 2008 (FR) 08 06446

(51) Int. Cl. G01R 27/26; B61L 23/00

(52) U.S. Cl. 324/678; 246/1 C

(57) ABSTRACT

A fail-safe system, notably for use in a railroad signaling system, comprising a test module with a photovoltaic coupler able to charge a capacitor. The energy stored in the capacitor provides power supply to a circuit under test. Advantageously, means of measuring a state of charge of the capacitor make it possible to quantify current leaks from the circuit under test.

### CROSS-REFERENCE TO RELATED APPLICATIONS

This application claims priority of French application no. FR 08/06446, filed Nov. 18, 2008, the disclosure of which is hereby incorporated by reference in its entirety.

### BACKGROUND OF THE INVENTION

1. Field of the Invention

The present invention relates to a fail-safe system and also relates to a test module. It applies notably to railroad signaling devices.

Intrinsically safe or fail-safe systems are necessary in all devices where the malfunctioning of one of their components or circuits can have consequences for the safety of persons. Such is the case for devices used in applications such as railroad signaling, but also in aeronautical instrumentation, nuclear power station control instrumentation, equipment used in the petrochemical industry, in medical instrumentation, and so on. In such devices, no anomaly, whatever it may be, should lead to the transmission of more permissive information than that provided in normal operation. Thus, it is necessary for the equipment implemented to be able to handle their functions without the safety characteristics of their components being able to be compromised. To this end, there are standards applicable to safety devices such as the standard IEC 61508—“Functional safety of electrical/electronic/programmable electronic safety-related systems”, or indeed for the specific example of railroad equipment, the standard EN 50129—“Safety related electronic systems for signaling”.

It is notably necessary, in the case of electronic devices, for any failure of any key component to be able to be diagnosed within the shortest possible time, in order for corrective actions to be taken. To this end, it is possible to carry out periodic tests on the devices. However, such tests often have the drawback of being intrusive, inasmuch as they require energy power supply for inputs or outputs of the device or certain of its components. Furthermore, it is essential to check that such tests cannot lead to positive results despite the failure of a component.

2. Discussion of the Background

There are a large number of fail-safe solutions known to those skilled in the art, notably in the railroad signaling industry. It is, for example, possible, for digital circuit inputs, to use solutions for designing circuits with enhanced reliability, such as Colpitts oscillators. In this same field, it is possible to secure digital circuit outputs by using networks of relays with interdependent contacts.

Nevertheless, such solutions do present drawbacks. On the one hand, the complexity of the electronic fail-safe circuits results in high development and production costs. On the other hand, when electromechanical relays are used, the latter offer a limited number of operation cycles, or a limited lifespan imposing tests that are close together in time and the preventive replacement of these relays during maintenance procedures. It should be noted that these drawbacks can adversely affect the exhaustivity of the tests; furthermore, excessively intrusive tests often result in disturbances to the operation of the devices under test that can represent threats to their safety.

### SUMMARY OF THE INVENTION

One purpose of the invention is to overcome the above-mentioned problems, by proposing a fail safe system that is capable of providing safe and effective power supply to the components or circuits under test or even to test circuits, and that does not compromise the operation of the devices in which they are integrated. Another advantage of the invention is linked to the low volume required for its implementation in devices, and to the low cost of the latter, while providing an optimum level of safety. Furthermore, the system according to the invention makes it possible to diagnose current leaks originating from the components or circuits under test, in order to initiate the use of backup devices if redundancies have been provided, or even trigger alerts, repair operations if necessary, and quite simply trigger measures to maximize safety, such as, for example, a signal prompting the trains to stop, all of these actions being, for example, controlled by a central control system. Finally, another advantage of the invention is that it can be applied equally to the testing of inputs or outputs of components or circuits under test.

To this end, the subject of the invention is a system including a fail safe function comprising at least one circuit test module, the test module comprising at least one circuit power supply means, the power supply means comprising an insulated photovoltaic coupler able to charge an energy storage means able to be discharged into the circuit under test, which can be a component or even a test circuit.

In one embodiment of the invention, the system also comprises means of measuring a state of charge of the energy storage means, determining a state of charge indicator.

In one embodiment of the invention, the state of charge indicator is a time representative of the discharge time of the energy storage means.

In one embodiment of the invention, the system also comprises warning means that are activated if a predetermined threshold value is crossed by said state of charge indicator.

In one embodiment of the invention, the system is characterized in that the energy storage means is a capacitor.

In one embodiment of the invention, the system is characterized in that said at least one component under test is at least one switch.

In a preferred embodiment of the invention, the switch is of field-effect transistor type.

Another subject of the invention is a railroad signaling system comprising a fail-safe system as described hereinabove.

Another subject of the invention is an electrical circuit test module, comprising at least one power supply means comprising an insulated photovoltaic coupler able to charge an energy storage means, able to be discharged into the electric circuit.

In one embodiment of the invention, the test module may further comprise means of measuring a state of charge of the energy storage means.

In a preferred embodiment of the invention, the energy storage means is a capacitor.

Another subject of the invention is a railroad signaling system including a fail-safe function, comprising at least one network of interconnected switches, able to control the power supply to a load, wherein each of the switches of the network is associated with a test module as described hereinabove.

In one embodiment of the invention, the railroad signaling system is noteworthy in that said at least one network of interconnected switches controlling the load comprises two networks of switches of P-channel field-effect transistor type and N-channel field-effect transistor type, each of the networks comprising two parallel branches, each of the parallel branches comprising two switches of P-channel field-effect transistor type or two switches of N-channel field-effect transistor type, each of the networks being connected between the positive terminal or negative terminal of a battery and one of the terminals of the load.

### BRIEF DESCRIPTION OF THE DRAWINGS

Other features and advantages of the invention will become apparent from reading the description, given by way of example, given in light of the appended drawings that represent:

FIG. 1, the circuit diagram of an exemplary embodiment of the invention applied to the power supply for a circuit under test;

FIG. 2, the circuit diagram of an exemplary embodiment of the invention applying to the detection of leak currents originating from a component or circuit under test;

FIGS. 3A and 3B, the circuit diagram of an exemplary embodiment of the invention applying to the measurement of leak currents on an actuator of N-channel field-effect transistor type (hereinafter designated MOSFET) and of P-channel MOSFET type respectively;

FIG. 4, the circuit diagram of an exemplary embodiment of the invention applying to a network of actuators of P- and N-channel MOSFET type;

FIG. 5, the circuit diagram of an exemplary embodiment of the invention applying to the protection of the input of a circuit.

### DESCRIPTION OF THE PREFERRED EMBODIMENTS

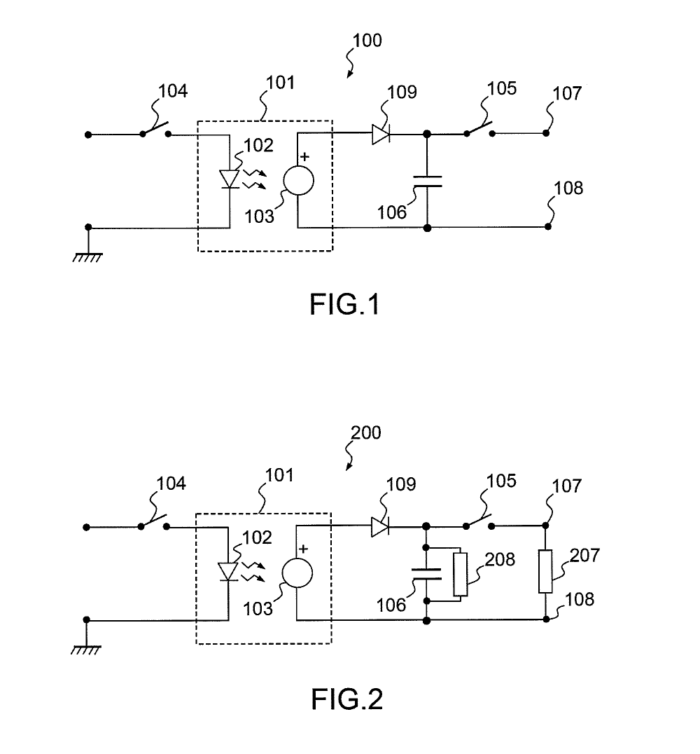

FIG. 1 shows the circuit diagram of an exemplary fail-safe system 100 according to the invention applied to the power supply for a circuit under test or a test circuit, not shown in the figure. This circuit under test is connected to input terminals 107 and 108. The system according to the invention includes a photovoltaic coupler 101, comprising a light-emitting device 102 and a photovoltaic cell 103 optically coupled but electrically insulated from one another. The photovoltaic coupler 101 is connected between a first switch 104 and a reference potential. The switch 104, for example an actuator, is connected to an energy source, for example a voltage loaded by a resistor that is not represented. The photovoltaic coupler 101 constitutes an energy source, its power being limited by the properties inherent to this component. For example, the maximum voltage at the terminals of the cell is limited to 10 volts, and the output current is of the order of a few microamperes. A capacitor 106 is connected between the terminals of the photovoltaic cell 103, for example via a diode 109. This capacitor typically offers a capacitance of the order of a microfarad. The diode 109 makes it possible to protect the anode of the photovoltaic cell 103 from returned electrical current. The capacitor 106 is connected to the circuit under test by the input terminals 107 and 108. A second switch 105 is connected between a first armature of the capacitor 106 and a first terminal 107. The second terminal 108 is connected to the second armature of the capacitor 106. The operation of the system can be broken down into three separate phases described hereinbelow:
A first phase of charging the capacitor 106. In this first phase, the first switch 104 is closed and the second switch 105 is open. The power delivered by the photovoltaic cell 103 is then stored in energy form in the capacitor 106. The duration of the first phase, of the order of a few seconds, is predetermined so as to ensure that the capacitor 106 is fully charged.
A second phase of discharging the capacitor 106. In this second phase, the first switch 104 is open and the second switch 105 is closed. During a time period of the order of a few milliseconds for example, the energy stored in the capacitor 106 is used to feed the circuit under test. The output impedance of the circuit 100 is such that the disturbance with respect to the circuit under test is of short duration, and thus has no impact on the correct operation of the circuit under test, or indeed this impact can easily be eliminated, for example by means of appropriate filters known to those skilled in the art, without in any way prejudicing the functionality of the circuit under test.
In a third phase, the first switch 104 is open, as is the switch 105. The system is then inactive, and when a new test must be carried out, the sequence can recommence with the first phase. It should be noted that the third phase is optional, the system being able to return to the first phase immediately after the end of the second phase if necessary.

One advantage of the invention is that the power delivered by the photovoltaic coupler 101 is limited, and cannot corrupt the circuit under test and compromise safety, even in the eventuality of the switches 104 and 105 remaining closed for a long time.

FIG. 2 shows the circuit diagram of an exemplary fail-safe system 200 according to the invention, applied to the detection of current leaks in a circuit under test that is not represented, connected in parallel with a capacitor 106. This circuit under test usually behaves as an open circuit. FIG. 2 differs from FIG. 1 in that a resistor 208, in parallel with the capacitor 106, represents the current leakage resistance in the circuit under test. Furthermore, the input terminals 107 and 108 are connected to a current measuring device 207. The operation of the system can be broken down into two distinct phases described hereinbelow:
A first phase of charging the capacitor 106. In this first phase, the duration of which is predetermined to ensure that the capacitor 106 is fully charged, the first switch 104 is closed and the second switch 105 is open. The capacitor 106 is charged, in the same way as previously described with reference to FIG. 1. This time, if a leak is present in the circuit under test, the leak resistance 208 absorbs a portion of the electrical power, and the capacitor 106 can be charged only partially.
A second phase of discharging the capacitor 106. In this second phase, the first switch 104 is open and the second switch 105 is closed; thus, the capacitor 106 is discharged into the measuring device 207. This device can, for example, comprise means for measuring the voltage at the terminals of the capacitor 106, or even means for measuring a capacitor discharge time, or even a time at the end of which the voltage at the terminals of the capacitor passes below a predetermined threshold. Obviously, other means of estimating the charge of the capacitor can be envisaged.

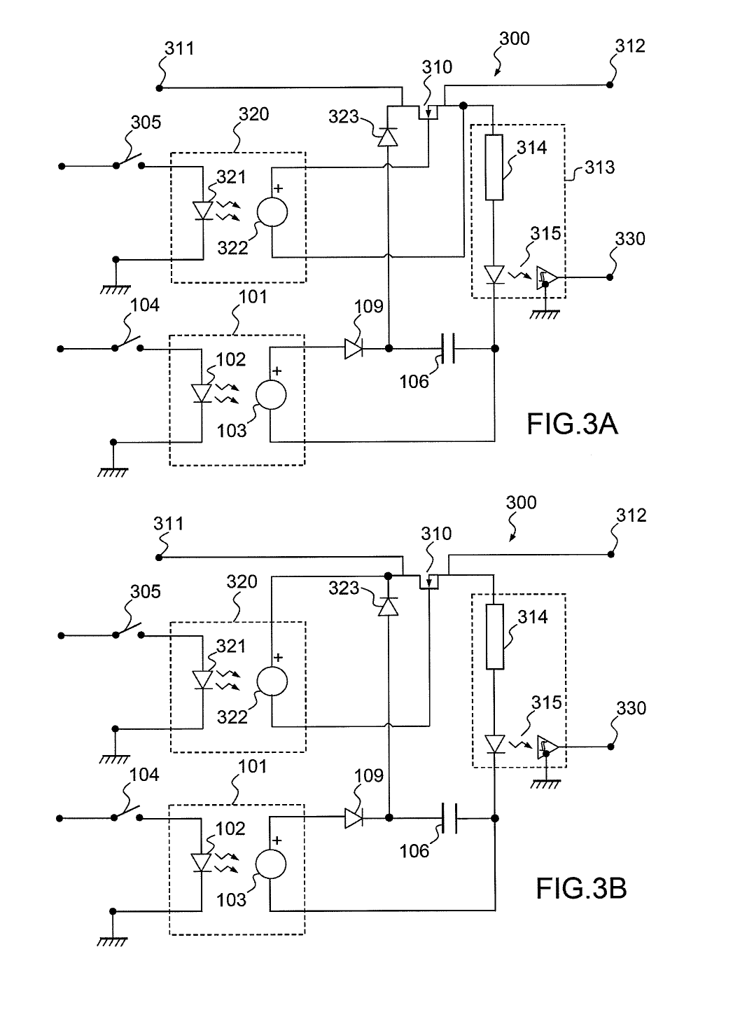

FIG. 3A shows the circuit diagram of a fail-safe system 300 according to the invention, applied by way of example to the detection of leak currents in a switch 310 of N-channel MOSFET type. A first photovoltaic coupler 320 comprising a light source 321 coupled to a photovoltaic cell 322 is used as energy source for the switch 310. The light emitter 321 is connected to an energy source via a first switch 305, and to a reference potential. The positive terminal of the photovoltaic cell 322 is connected to the gate of the MOSFET switch 310. The negative terminal of the cell 322 is connected to the drain of the MOSFET switch 310. A second photovoltaic coupler 101 comprising a light emitter 102 coupled to a photovoltaic cell 103 is used as energy source for charging a capacitor 106. The light emitter 102 is connected to an energy source via a second switch 104, and to the reference potential. The positive terminal of the photovoltaic cell 103 is connected to a diode 109. The diode 109 is connected to the source of the MOSFET switch 310 via a diode 323. The diodes 109 and 323 protect the photovoltaic cell 103 against returned current. The diode 109 is furthermore connected to the first armature of a capacitor 106. The negative terminal of the photovoltaic cell 103 is connected to the second armature of the capacitor 106. The source of the MOSFET switch 310 is furthermore connected to an input 311, the drain to an output 312. The drain is furthermore connected to a current measuring device 313, in this example consisting of a resistor 314 connected to the primary of a Schmitt trigger photocoupler 315. The secondary of this photocoupler is connected to a test output 330. The operation of the system can be broken down into two distinct phases described hereinbelow:
In a first phase, the first switch 305 and therefore the MOSFET switch 310 are open, and the second switch 104 is closed. Thus, in a manner similar to that described above with reference to FIG. 2, the second photovoltaic coupler 101 charges the capacitor 106, for a predetermined duration to ensure that the latter is fully charged. Assuming that the MOSFET switch 310 presents current leaks, the charge of the capacitor 106 can be only partial.
In a second phase, the second switch 104 is open and the first switch 305 is closed. The MOSFET switch 310 is then closed. In this example, the output 330 is temporarily active, for a duration dependent on the electric current passing through the resistor 314. Thus, a leak current in the actuator 310 is reflected in a duration of the active state of the photocoupler 315 that is less than a predetermined threshold. Obviously, other types of known devices able to determine a state of charge of the capacitor 106 can be envisaged.

FIG. 3B is similar to FIG. 3A. It relates to the case where the component under test is a P-channel MOSFET type switch 340. The description given with reference to FIG. 3A applies to FIG. 3B, except for the fact that the positive terminal of the photovoltaic cell 322 of the first coupler 320 is connected to the source of the MOSFET switch 340. The negative terminal of the cell 322 is connected to the gate of the MOSFET switch 340.

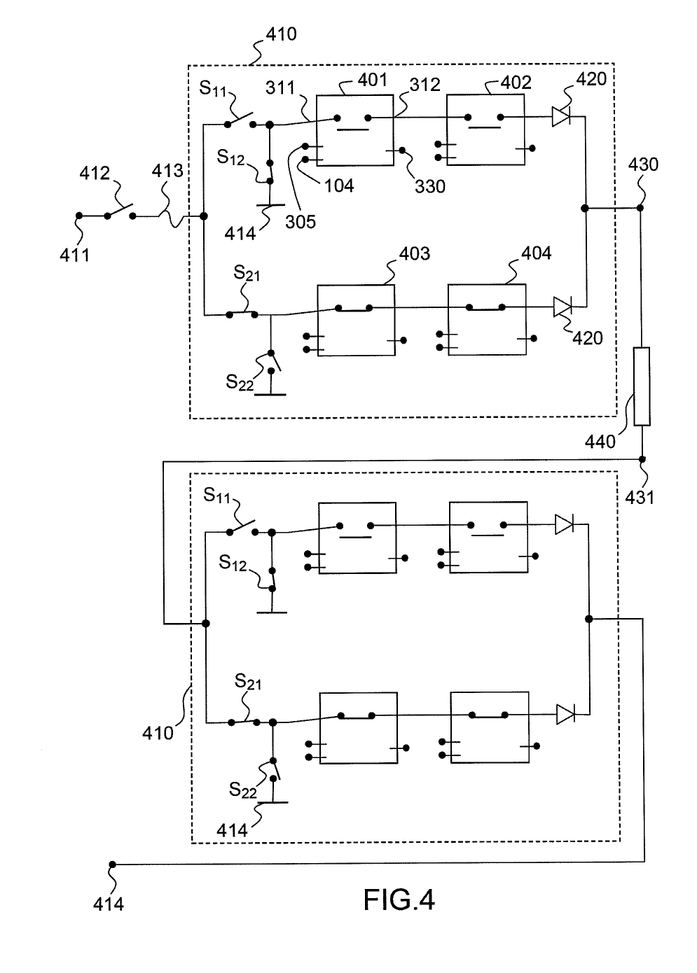

FIG. 4 shows the circuit diagram of one embodiment of the invention, applied by way of example to a secured control system comprising P- and N-channel MOSFET type switches. A system 400 according to the invention comprises two networks 410 of four modules 401, 402, 403 and 404 fed by a battery and connected to a load 440. The input of the network 410 is connected to the positive terminal of the battery via a disconnecting relay 412 and a fuse 413. The input of the network 410 is furthermore connected to two parallel branches, each of them comprising two modules connected in series. A first parallel branch comprises the first module 401, in this example a system comprising a switch of N-channel MOSFET type as represented in FIG. 3A, in series with the second module 402, comprising a P-channel MOSFET type switch as represented in FIG. 3B, the second module being mounted in series with a protection diode 420. Two switches S11 and S12 are connected between the input of the network 410 and the input of the first module 401. The first switch S11 is connected between the input of the network 410 and a terminal of the second switch S12. The other terminal of the second switch S12 is connected to the negative terminal 414 of the battery. The output of the first module 401 is connected to the input of the second module 402. The output of the second module 402 is connected to a first terminal 430 of the load 440. A second parallel branch comprises the third module 403, in this example a system comprising a switch of P-channel MOSFET type as represented in FIG. 3B, in series with the fourth module 404, comprising a switch of N-channel MOSFET type as represented in FIG. 3A, the fourth module being mounted in series with a protection diode 420. Two switches S21 and S22 are connected between the input of the network 410 and the input of the third module 403. The first switch S21 is connected between the input of the network 410 and a terminal of the second switch S22. The other terminal of the second switch S22 is connected to the negative terminal 414 of the battery. The output of the third module 403 is connected to the input of the fourth module 404. The output of the fourth module 404 is connected to the first terminal 430 of the load 440. A second terminal 431 of the load 440 is connected to the input of a second network 410, the output of which is connected to the negative terminal 414 of the battery. Each of the modules 401, 402, 403 and 404 presents an input 311, an output 312, a first switch 305 and a second switch 104, and a test output 330, according to the descriptions given with reference to FIGS. 3A and 3B. Each of these modules is thus able to be tested independently of the other modules. Thus, any failure of one of the devices forming this system can be diagnosed rapidly.

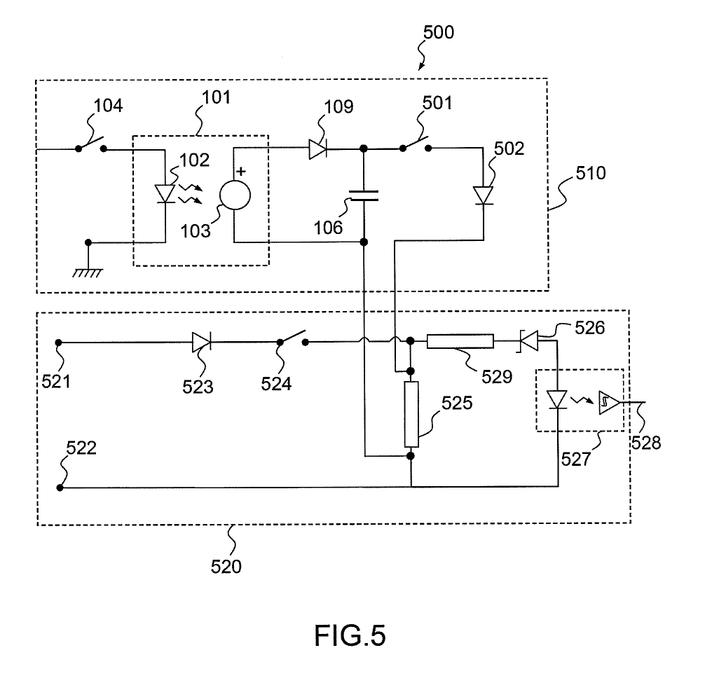

FIG. 5 shows the circuit diagram of one embodiment of the invention applied by way of example to the testing of the input of an electrical system. Such a fail-safe system according to the invention comprises a circuit 520 and a test module 510. Advantageously, the test module 510 is integrated in the circuit 520. The input 521 of the circuit 520 is tested by the test module 510. The input 521 is connected to a first switch 524 via a protection diode 523. The first switch 524 is furthermore connected to a Zener diode 526. The Zener diode 526 is intended to supply a voltage threshold to the primary of a Schmitt trigger coupler 527. The secondary of this coupler is connected to an output 528. The primary of the coupler 527 is linked to a reference potential 522. A line resistance 529 is connected to the diode 526, just upstream of the latter. A resistor 525 sets the input impedance. The test module 510 is similar to the systems described above with reference to the preceding figures. This test module therefore comprises a photovoltaic coupler 101 used as an energy source for charging a capacitor 106. The photovoltaic coupler 101 comprises a light emitter 102 connected to an energy source via a second switch 104, and to the reference potential. The light emitter 102 is coupled to a photovoltaic cell 103. The positive terminal of the photovoltaic cell 103 is connected to a diode 109. The diode 109 is connected to the first armature of a capacitor 106. The negative terminal of the cell 103 is connected to the second armature of the capacitor 106. The latter is furthermore connected to a first terminal of the resistor 525. The first armature of the capacitor 106 is furthermore connected to the first terminal of a third switch 501. The second terminal of the switch 501 is connected to the second terminal of the resistor 525 via a protection diode 502. The operation of the system can be broken down into two distinct phases described hereinbelow:
In a first phase, the third switch 501 is open; thus, the test module 510 is disconnected from the circuit 520. The first switch 524 is closed. Thus, the input 521 is read and transmitted to the output 528. The second switch 104 is closed, therefore the capacitor 106 is charged.
In a second phase, the second switch 104 is open. The first switch 524 is open, and the output 528 becomes inactive. The third switch 501 is closed, so the capacitor 106 is discharged into the circuit 520. The result of this is a pulse on the output 528. Measuring means, not represented here, can be used to characterize this pulse. For example, by measuring the duration of the pulse, it is possible to detect the increase in the resistance 525, and a modification of the input voltage threshold, conditioned by the Zener diode 526.

1. A system including a fail-safe function comprising at least one circuit test module, the test module comprising at least one circuit power supply means, the power supply means comprising an insulated photovoltaic coupler able to charge an energy storage means, able to be discharged into the circuit under test, the testing of the circuit comprising at least one first phase of charging the energy storage means and a second phase of discharging the energy storage means.

2. The fail-safe system as claimed in claim 1, wherein it also comprises means of measuring a state of charge of the energy storage means.

3. The fail-safe system as claimed in claim 2, wherein measured state of charge is a time representative of the discharge time of the energy storage means.

4. The fail-safe system as claimed in claim 2, further comprising warning means activated if a predetermined threshold value is crossed by measured state of charge.

5. The fail-safe system as claimed in claim 1, wherein said energy storage means is a capacitor.

6. The fail-safe system as claimed in claim 1, wherein said at least one component under test is at least one switch.

7. The fail-safe system as claimed in claim 1, wherein said at least one component under test is at least one switch of field-effect transistor type.

8. A railroad signaling system comprising a fail-safe system as claimed in claim 1.

9. An electrical circuit test module, which comprises at least one power supply means comprising an insulated photovoltaic coupler able to charge an energy storage means, able to be discharged into the electric circuit.

10. The electrical circuit test module as claimed in claim 9, which also comprises means of measuring a state of charge of the energy storage means.

11. The test module as claimed in claim 9, wherein the energy storage means is a capacitor.

12. The test module as claimed in claim 10, wherein the energy storage means is a capacitor.

13. A railroad signaling system including a fail-safe function, comprising at least one network of interconnected switches, able to control the power supply to a load, wherein each of the switches of the network is associated with a test module as claimed in claim 9.

14. The railroad signaling system as claimed in claim 13, wherein said at least one network of interconnected switches controlling the load comprises two networks of switches of P-channel field-effect transistor type and N-channel field-effect transistor type, each of the networks comprising two parallel branches, each of the parallel branches comprising two switches of P-channel field-effect transistor type or two switches of N-channel field-effect transistor type, each of the networks being connected between the positive terminal or negative terminal of a battery and one of the terminals of the load.
